(19) United States
(12) Patent Application Publication
(10) Pub. No.: US 2017/0170382 A1
(43) Pub. Date: Jun. 15, 2017

(54) THERMOELECTRICAL DEVICE

(71) Applicant: Mahle International GmbH, Stuttgart (DE)

(72) Inventors: Thomas Himmer, Reichenbach (DE); Michael Moser, Ellwangen (DE)

(21) Appl. No.: 15/373,407

(22) Filed: Dec. 8, 2016

(30) Foreign Application Priority Data
Dec. 9, 2015 (DE) 10 2015 224 712.0

(51) Int. Cl. H01L 35/32

(52) U.S. Cl. CPC H01L 35/325

(57) ABSTRACT

A thermoelectrical device, for example a thermoelectrical generator, may include a plurality of thermoelectrical modules stacked on top of each other along a stacking direction, each of which may include a number of thermoelectrical elements. A plurality of first heat-conducting elements may be arranged to thermally couple the thermoelectrical modules to a first heat reservoir. A plurality of second heat-conducting elements may be arranged to thermally couple the thermoelectrical modules to a second heat reservoir. The plurality of first heat-conducting elements, in a cross-section axially or vertically to the stacking direction, may extend transversely to the plurality of second heat-conducting elements.

### CROSS-REFERENCE TO RELATED APPLICATIONS

This application claims priority to German Patent Application No. 10 2015 224 712.0, filed Dec. 9, 2015, the contents of which are hereby incorporated by reference in its entirety.

### TECHNICAL FIELD

The invention relates to a thermoelectrical device, in particular a thermoelectrical generator.

### BACKGROUND

The term “thermoelectricity” is understood to mean the mutual interaction between temperature and electricity and their conversion into each other. Thermoelectrical elements make use of this interaction in that they act as thermoelectrical generators generating electric energy. Thermoelectrical generators convert temperature differences into an electric potential difference, i.e. an electric voltage. In this way a heat current can be converted into an electric current. For example, thermoelectrical modules of this kind can be used for the recovery of waste heat, as for example in a combustion engine. Surplus waste heat, for example, in relation to an environment or in relation to a coolant, comprises a temperature difference, which can be utilised to generate a heat current, which with the aid of such thermoelectrical modules can be converted into an electric current, a fact, which corresponds to said waste heat recovery.

A thermoelectrical module typically comprises a number of thermoelectrical elements in the form of positively and negatively doped semiconductor materials, which are electrically connected via a number of conductor bridges. The thermoelectrical module, on its cold side, comprises an outer wall, which can be called a cold-side wall and which is firmly connected to a number of cold-side conductor bridges in a heat-conducting and electrically insulated manner. Analogously thereto the thermoelectrical module, on its warm side, comprises an outer wall forming a warm-side wall, which is firmly connected to a number of warm-side conductor-bridges in a heat-conducting and electrically insulated manner. The thermoelectrical elements are arranged between the cold-side wall and the warm-side wall, so that they extend between the cold-side and warm-side conductor bridges.

A thermoelectrical module of this kind is known, for example from the DE 1 539 322 A.

It is also known from the state of the art to stack a number of thermoelectrical modules on top of each other, in order to improve in this way the efficiency of the thermoelectrical device.

It is the requirement of the present invention, to propose new ways in the development of thermoelectrical devices, in particular if these are realised as thermoelectrical generators.

This requirement is met by the subject of the independent patent claim(s). Preferred embodiments are the subject of the dependant patent claims.

### SUMMARY

The basic idea of the invention thus consists in stacking individual thermoelectrical modules of the thermoelectrical device, in which the thermoelectrical elements are present, on top of each other and in arranging a first or second heat-conducting element serving as a thermal contact with a first or second heat reservoir, between two adjacent modules. With this arrangement the first heat reservoir can be flown through by a so-called hot medium and the second reservoir can be flown through by a cold medium and vice versa. The terms “hot medium” and “cold medium” in this case are understood here to mean two fluids with different temperatures, wherein one of the two fluids, i.e. the hot medium, comprises a higher temperature than the second fluid, i.e. the cold medium. The thermoelectrical modules are therefore coupled via the first/the second heat-conducting elements to the two different-temperature fluids. The temperature difference existing between the two fluids is transmitted via the heat-conducting elements to the thermoelectrical modules, which, following the active principle of a thermoelectrical generator, can generate from the temperature difference an electrical potential difference, i.e. an electrical voltage. This allows the two heat reservoirs to be laterally attached at an extremely short distance from the thermoelectrical modules.

In summary this leads to a very good thermal coupling between the thermoelectrical modules and the heat reservoirs, which ensures a high degree of efficiency of the thermoelectrical device, in particular if this is operated as a thermoelectrical generator. In addition, the thermoelectrical device according to the invention which is proposed here, requires only a small amount of constructional space.

A thermoelectrical device according to the invention, in particular a thermoelectrical generator, comprises a plurality of thermoelectrical modules stacked on top of each other along a stacking direction. Each thermoelectrical module comprises a number of thermoelectrical elements. Furthermore the thermoelectrical device comprises a plurality of first heat-conducting elements, which thermally couple the thermoelectrical module to a first heat-reservoir which can be flown through by a hot medium. In a corresponding manner a plurality of second heat-conducting elements thermally couple the thermoelectrical modules to a second heat reservoir, which can be flown through by a cold medium. According to the invention the first heat-conducting elements, in a cross-section vertically to the stacking direction, extend transversely to the second heat-conducting elements.

In a preferred embodiment the first and second heat-conducting elements comprise an elongate shape so that a direction in longitudinal extension of the first heat-conducting elements extends transversely to a direction in longitudinal extension of the second heat-conducting elements. An elongate shape is understood to mean that a length of the heat-conducting element is larger than a width of the heat conducting element. This measure allows the fluid lines to be attached laterally in the immediate vicinity of the thermoelectrical modules.

Preferably at least one thermoelectrical module comprises a hot side, which is thermally connected to a first heat-conducting element. Furthermore at least one thermoelectrical module comprises a cold side, which is thermally connected to a second heat-conducting element. Especially preferably this applies to all thermoelectrical modules. In this way it is possible to ensure an effective thermal coupling between the thermoelectrical modules and the heat reservoirs. In one variant the first heat-conducting element can be connected to the cold side and the second heat-conducting element can be connected to the hot side.

In a further preferred embodiment a first heat-conducting element thermally connected to the first heat reservoir, or a second heat element thermally connected to the second heat reservoir is arranged respectively in stacking direction between two adjacent thermoelectrical modules. In this way the desired thermal coupling of each thermoelectrical module to both the first and the second heat reservoir can be ensured along with savings in constructional space.

Especially conveniently a first heat-conducting element and a second heat-conducting element respectively alternate in stacking direction. This makes it possible, in a constructionally very simple manner, to effect the operationally required coupling of the thermoelectrical modules both to the first and the second heat reservoir.

One advantageous further development of the invention, where the heat conducting elements comprise two longitudinal and two transverse sides, has been proven to be particularly space-saving. In this variant a longitudinal side of a first heat-conducting element extends transversely to the longitudinal side of a second heat-conducting element.

In one advantageous further development the first heat reservoir comprises two first fluid lines, which can be flown through by a hot medium and which, in cross-section vertically to the stacking direction, lie opposite each other, and which are arranged at the two longitudinal ends of the first heat-conducting elements. Alternatively or additionally the second heat reservoir comprises two second fluid lines, which, in cross-section vertically to the stacking direction, lie opposite each other and which are arranged at the two longitudinal ends of the second heat-conducting elements.

Especially preferably the two first fluid lines, in cross-section vertically to the stacking direction, are essentially arranged offset by 90° from the two second fluid lines. In this way the constructional space required for the thermoelectrical device in lateral direction, i.e. orthogonally to the stacking direction, can be kept small.

In another preferred embodiment the direction in longitudinal extension discussed above is defined by a longitudinal side of the first heat-conducting elements. Similarly a direction in transverse extension is defined by a transverse side of the first heat-conducting elements. In this variant, in which the components lie especially close to each other, the two first fluid lines lie opposite each other along the direction in transverse extension.

Conveniently the fluid lines, in cross-section vertically to the stacking direction, may essentially comprise the geometry of a rectangle. A respective first or second fluid line is arranged along its longitudinal side on a transverse side of the respective heat-conducting element. This measure allows for a large contact surface between the heat-conducting elements and the fluid lines in order to ensure a highly effective thermal contact.

Preferably the two first fluid lines and the two second fluid lines respectively extend along the stacking direction. In this way a random number of thermoelectrical modules can, in principle, be stacked on top of each other and coupled to the fluid lines.

In a preferred embodiment at least one thermoelectrical module is arranged in the cross-section vertically to the stacking direction, centred relative to the first and second heat-conducting elements.

It is particularly convenient if at least one thermoelectrical module comprises the geometry of a square in the cross-section vertically to the stacking direction. The whole geometry of the thermoelectrical device resulting from this measure leads to a particularly uniform thermal contact of the heat-conducting elements with the thermoelectrical module.

Preferably the fluid lines lengthen the first/the second heat-conducting elements along the respective direction in longitudinal extension.

In a further preferred embodiment at least one fluid line is configured in two pieces with a line floor and a line lid. Especially preferably this applies to all fluid lines of the thermoelectrical device. In this variant the line floor is mechanically and thermally connected to the heat-conducting elements. Such a configuration comprising an at least two-piece fluid line makes assembly of the fluid lines easier.

It is particularly convenient to form the heat conducting elements as shaped sheet metal parts. Manufacturing costs when using this measure are particularly low.

A particularly good mechanical attachment of the heat-conducting elements to the thermoelectrical modules is achieved if the heat-conducting elements form a press-fit with the thermoelectrical modules.

Preferably the heat-conducting elements are attached to the fluid lines by means of material bonding, in particular by means of a soldered connection. This measure ensures a reliable mechanical attachment of the heat-conducting elements to the fluid lines. At the same time good thermal contact is ensured.

It is especially convenient for the thermoelectrical modules to comprise, in the cross section vertically to the stacking direction, the geometry of a square. The 90°-rotational symmetry associated therewith permits the first and second heat-conducting elements to be manufactured as identical parts. This leads to a reduction in manufacturing costs which is not negligible.

Further important features and advantages of the invention are revealed in the sub-claims, the drawings and the associated description of the figures with reference to the drawings.

It is understood that the features mentioned above and to be explained further below cannot only be used in the respectively cited combination but also in other combinations or on their own without leaving the scope of the invention.

Preferred exemplary embodiments of the invention are depicted in the drawings and are further explained in the description below, where identical reference symbols refer to identical or similar or functionally identical components.

### BRIEF DESCRIPTION OF THE DRAWINGS

In the schematic drawings,

FIG. 1 shows an example of a thermoelectrical device according to the invention in a longitudinal section along its stacking direction,

FIG. 2 shows the thermoelectrical device of FIG. 1 in a cross-section vertically to the stacking direction.

### DETAILED DESCRIPTION

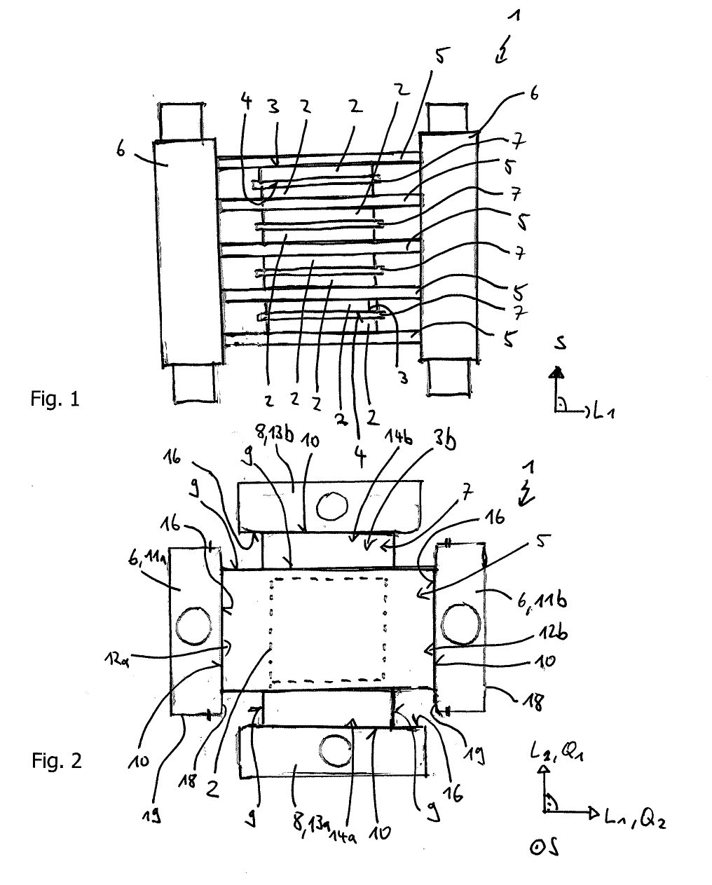

FIG. 1 shows an example of a thermoelectrical device 1 according to the invention, which can be used as a thermoelectrical generator. The thermoelectrical device 1 comprises a plurality of thermoelectrical modules 2 stacked on top of each other along a stacking direction S, each of which comprises a number of thermoelectrical elements (not shown in the figures). The construction and arrangement of thermoelectrically active elements of individual thermoelectrical modules 2 are known to the expert and not the core subject of the present invention, thereby obviating the need for a detailed description. FIG. 1 shows the thermoelectrical device 1 in a longitudinal section along its stacking direction S. FIG. 2 shows the thermoelectrical device 1 in a cross-section vertically to the stacking direction S.

Each thermoelectrical module 2 comprises a number of thermoelectrically active elements. The thermoelectrically active elements are p- and n-type semiconductors, which are electrically connected to each other in a manner known to the expert and which form a hot side 3 and a cold side 4 of the respective thermoelectrical module 2. In the exemplary scenario the hot sides 3 of the thermoelectrical modules 2 are connected to the first heat-conducting elements 5. Similarly the cold sides 4 of the thermoelectrical modules 2 are connected to the second heat-conducting elements 7.

The thermoelectrical device 1 comprises a plurality of heat-conducting elements 5, which thermally couple the thermoelectrical modules 2 to a first heat reservoir 6. Furthermore the thermoelectrical device 1 comprises a plurality of second heat-conducting elements 7, which thermally couple the thermoelectrical modules 2 to a second heat reservoir 8.

FIG. 2 shows the thermoelectrical device 1 in a cross-section vertically to the stacking direction S. It can be seen that the first and second heat-conducting elements 5, 7 comprise an elongate shape so that a direction L1 in longitudinal extension of the first heat-conducting elements 5 extends transversely to a direction L2 in longitudinal extension of the second heat-conducting elements 7.

The first and second heat-conducting elements 5, 7 each comprise two longitudinal sides 9 and two transverse sides 10. The first direction L1 in longitudinal extension extends in parallel to the longitudinal side 9 of the first heat-conducting elements 5. The second direction L2 in longitudinal extension extends in parallel to the longitudinal side 9 of the second heat-conducting elements 7.

As clearly illustrated in FIG. 2 the longitudinal side 9 of a first heat-conducting element 5 extends transversely to a longitudinal side 9 of a second heat-conducting element 7. The same applies mutatis mutandis to the transverse sides 10 of the first and second heat-conducting elements 5, 7. Therefore, according to FIG. 2, the first heat-conducting elements 5, in cross-section vertically to the stacking direction S, extend transversely to the second heat-conducting elements 7.

Again looking at FIG. 1, it can be recognised that either a first heat-conducting element 5 or a second heat-conducting element 7 is respectively arranged between two adjacent thermoelectrical modules 2 in stacking direction S. A first heat-conducting element 5 and a second heat-conducting element 7 respectively alternate along the stacking direction S. In addition FIGS. 1 and 2 show that the first heat reservoir 6 comprises two first fluid lines 11a, 11b, which can be flown through by a hot medium. The two first fluid lines, in the cross-section in FIG. 2, are arranged at the two longitudinal ends 12a, 12b of the first heat-conducting elements 5. The second heat reservoir 8 comprises two second fluid lines 13a, 13b, which are flown through by a cold medium, and which lie opposite each other in the cross-section in FIG. 2 and which are arranged at the two longitudinal ends 14a, 14b of the second heat-conducting elements 7. The two first fluid lines 11a, 11b, in cross-section vertically to the stacking direction S, are essentially arranged offset by 90° from the two second fluid-lines 13a, 13b.

The hot sides 3 of the thermoelectrical modules 2 are thus connected to the hot medium via the first heat-conducting elements 5. Similarly the cold sides 4 of the thermoelectrical modules 2 are connected to the cold medium via the second heat-conducting elements 7.

The first direction L1 in longitudinal extension is fixed by the position of the longitudinal sides 9 of the first heat-conducting elements 5. Similarly a first direction Q1 in transverse extension is defined by the position of the transverse sides 10 of the first heat conducting elements 5. A second direction Q2 in transverse extension is defined by the position of the transverse sides 10 of the second heat-conducting elements 7.

As clearly illustrated in FIG. 2, the two first fluid lines 11a, 11b lie opposite each other along the direction L1 in longitudinal extension. The second two fluid lines 13a, 13b lie opposite each other along the first direction Q1 in transverse extension. The first and second fluid lines 11a, 11b, 13a, 13b respectively, in the cross-section of FIG. 2 vertically to the stacking direction S, comprise essentially the geometry of a rectangle. The fluid lines 11a, 11b, 13a, 13b, along their longitudinal side 16, are arranged respectively on the transverse side 10 of the respective first or second heat-conducting element 5, 7.

The thermoelectrical modules 2, in cross-section vertically to the stacking direction S, are arranged centred relative to the first and second heat-conducting elements 5, 7 and have the geometry of a square. The fluid lines 11a, 11b, 13a, 13b lengthen the first/the second heat-conducting elements 5, 7 along the respective direction L1, L2 in longitudinal extension.

Both the two first fluid lines 11a, 11b flown through by the hot medium and the two second fluid lines 13a, 13b flown through by the cold medium preferably extend along the stacking direction S. The fluid lines 11a, 11b, 13a, 13b are constructed in two pieces, each with a line floor 18 and a line lid 19. In the exemplary figures the line lid 19 is connected mechanically and thermally to the first/the second heat-conducting elements 5, 7. Conveniently the first and second heat-conducting elements 5, 7 are configured as shaped sheet metal parts. The thermoelectrical modules 2 are connected to the first/the second heat-conducting elements 5, 7 by means of a press fit. The first and second heat-conducting elements 5, 7 are attached to the first/the second fluid lines 11a, 11b, 13a, 13b by means of material bonding, in particular by means a soldered connection.

1. A thermoelectrical device, comprising:
a plurality of thermoelectrical modules stacked on top of each other along a stacking direction, the plurality of thermoelectrical modules respectively including a number of thermoelectrical elements;
a plurality of first heat-conducting elements arranged to thermally couple the plurality of thermoelectrical modules to a first heat reservoir, the first heat reservoir flowable through by a hot medium; and
a plurality of second heat-conducting elements arranged to thermally couple the plurality of thermoelectrical modules to a second heat reservoir, the second heat reservoir flowable through by a cold medium;
wherein the plurality of first heat-conducting elements extend transversely to the plurality of second heat-conducting elements with respect to a cross-section axial to the stacking direction.

2. The thermoelectrical device according to claim 1, wherein the plurality of first heat-conducting elements and the plurality of second heat-conducting elements respectively include an elongate shape having a longitudinal extension, and wherein a direction in the longitudinal extension of the plurality of first heat-conducting elements extends transversely to a direction in the longitudinal extension of the plurality of second heat-conducting elements.

3. The thermoelectrical device according to claim 1, wherein each of the plurality of thermoelectrical modules includes a hot side thermally coupled to one of the plurality of first heat-conducting elements and the plurality of second heat-conducting elements, and a cold side thermally coupled to the other of the plurality of first heat-conducting elements and the plurality of second heat-conducting elements.

4. The thermoelectrical device according to claim 1, wherein at least one of (i) at least one of the plurality of first heat-conducting elements thermally connected to the first heat reservoir and (ii) at least one of the plurality of second heat-conducting elements thermally connected to the second heat reservoir is arranged in the stacking direction between two adjacent thermoelectrical modules.

5. The thermoelectrical device according to claim 1, wherein a respective one of the plurality of first heat-conducting elements alternates with a respective one of the plurality of second heat-conducting elements along the stacking direction.

6. The thermoelectrical device according to claim 1, wherein at least one of the plurality of first heat-conducting elements and the plurality of second heat-conducting elements each have a longitudinal side and a transverse side, and wherein the longitudinal side of a respective one of the plurality of first heat-conducting elements extends transversely to the longitudinal side of a respective one of the plurality of second heat-conducting elements.

7. The thermoelectrical device according to claim 1, wherein the first heat reservoir includes at least two fluid lines flowable through by a hot medium, wherein the at least two fluid lines in a cross-section axial to the stacking direction lie opposite each other and are arranged at a respective longitudinal ends of the plurality of first heat-conducting elements; and
wherein the second heat reservoir includes at least two other fluid lines flowable through by a cold medium, wherein the at least two other fluid lines in a cross-section axial to the stacking direction lie opposite each other and are arranged at a respective longitudinal ends of the plurality of second heat-conducting elements.

8. The thermoelectrical device according to claim 1, wherein the first heat reservoir includes at least two first fluid lines arranged in the cross-section axial to the stacking direction, offset by approximately 90° from at least two second fluid lines of the second heat reservoir.

9. The thermoelectrical device according to claim 6, wherein the plurality of first heat-conducting elements are structured with an elongate shape having a direction in a longitudinal extension defined by the longitudinal side and a direction in a transverse extension defined by the transverse side, and wherein the first heat reservoir includes at least two first fluid lines that lie opposite each other along the direction in the longitudinal extension of the plurality of first heat-conducting elements and the second heat reservoir includes at least two second fluid lines that lie opposite each other along the direction in the transverse extension of the plurality of first heat-conducting elements.

10. The thermoelectrical device according to claim 1, wherein at least one of the first heat reservoir and the second heat reservoir includes a number of fluid lines that respectively have a substantially rectangular geometry in the cross-section axial to the stacking direction, and wherein a respective one of the number of fluid lines has a longitudinal side arranged on a respective transverse side of at least one of the plurality of first heat-conducting elements and the plurality of second heat-conducting elements.

11. The thermoelectrical device according to claim 7, wherein at least one of (i) the at least two fluid lines of the first heat reservoir have a longitudinal side extending across the entire transverse side of the plurality of first heat-conducting elements, and (ii) the at least two other fluid lines of the second heat reservoir having a longitudinal side extending across the entire transverse side of the plurality of second heat-conducting elements.

12. The thermoelectrical device according to claim 7, wherein at least one thermoelectrical module, in the cross-section axial to the stacking direction, is arranged centred with respect to the plurality of first heat-conducting elements and the plurality of second heat-conducting elements.

13. The thermoelectrical device according to claim 7, wherein at least one thermoelectrical module, in the cross-section axial to the stacking direction, includes a square geometry.

14. The thermoelectrical device according to claim 7, wherein the at least two fluid lines of the first heat reservoir and the at least two other fluid lines of the second heat reservoir lengthen the plurality of first heat-conducting elements and the plurality of second heat-conducting elements, respectively, along a respective direction in a longitudinal extension.

15. The thermoelectrical device according to claim 7, wherein the at least two fluid lines of the first heat reservoir and the at least two other fluid lines of the second heat reservoir respectively extend essentially along the stacking direction.

16. The thermoelectrical device according to claim 7, wherein at least one fluid line is configured in at least two pieces including a line floor and a line lid, wherein at least one of the line floor and the line lid is mechanically and thermally connected to a corresponding one of the plurality of first heat-conducting elements or the plurality of second heat conducting elements.

17. The thermoelectrical device according to claim 1, wherein the plurality of first heat-conducting elements and the plurality of second heat-conducting elements are each structured as a shaped sheet metal part.

18. The thermoelectrical device according to claim 1, wherein the plurality of thermoelectrical modules together with the plurality of first heat-conducting elements and the plurality of second heat-conducting elements define a press-fit.

19. The thermoelectrical device according to claim 1, wherein the plurality of first heat-conducting elements and the plurality of second heat-conducting elements are attached to corresponding fluid lines of the first heat reservoir and the second heat reservoir, respectively, via a material bond connection.

20. A thermoelectrical generator, comprising:
a plurality of thermoelectrical modules stacked on top of each other along a stacking direction, the plurality of thermoelectrical modules respectively including a number of thermoelectrical elements;
a first heat reservoir including at least two first fluid lines flowable through by a hot medium;
a second heat reservoir including at least two second fluid lines flowable through by a cold medium;
a plurality of first elongate shaped heat-conducting elements arranged to thermally couple the plurality of thermoelectrical modules to the first heat reservoir;
a plurality of second elongate shaped heat-conducting elements arranged to thermally couple the plurality of thermoelectrical modules to the second heat reservoir;
wherein the plurality of first heat-conducting elements are arranged along a longitudinal extension to extend transversely to a longitudinal extension of the plurality of second heat-conducting elements; and
wherein the at least two first fluid lines of the first heat reservoir are arranged at a respective transverse side of the plurality of first heat-conducting elements, and the at least two second fluid lines of the second heat reservoir are arranged at a respective transverse side of the plurality of second-heat conducting elements.
